(19) United States
(12) Patent Application Publication
(10) Pub. No.: US 2022/0282062 A1
(43) Pub. Date: Sep. 8, 2022

(54) POLYMER-BASED PIEZOELECTRIC COMPOSITE MATERIAL AND METHOD FOR PRODUCING RAW-MATERIAL PARTICLES FOR COMPOSITE

(71) Applicant: FUJIFILM Corporation, Tokyo (JP)

(72) Inventor: Tetsu MIYOSHI, Minamiashigara-shi (JP)

(73) Assignee: FUJIFILM Corporation, Tokyo (JP)

(21) Appl. No.: 17/827,161

(22) Filed: May 27, 2022

Related U.S. Application Data
(63) Continuation of application No. PCT/JP2020/041068, filed on Nov. 2, 2020.

(30) Foreign Application Priority Data
Nov. 28, 2019 (JP) 2019-215588

(51) Int. Cl. C08K 3/22; C08K 7/00

(52) U.S. Cl. CPC C08K 3/22; C08K 7/00; C08K 2003/2244; C08K 2003/2234; C08K 2003/2237

(57) ABSTRACT

An object of the present invention is to provide a polymer-based piezoelectric composite material including lead zirconate titanate particles in a matrix consisting of a polymer material, the polymer-based piezoelectric composite material having a high piezoelectric characteristic; and a method for producing raw-material particles for a composite, the raw-material particles being used in the polymer-based piezoelectric composite material. The object is accomplished by a configuration in which the lead zirconate titanate particles include a polycrystalline material, a crystal structure of primary particles constituting the polycrystalline material of the lead zirconate titanate particles includes tetragonal particles, and a volume fraction occupied by the tetragonal particles is 80% or more.

### CROSS-REFERENCE TO RELATED APPLICATIONS

This application is a Continuation of PCT International Application No. PCT/JP2020/041068 filed on Nov. 2, 2020, which claims priority under 35 U.S.C. § 119(a) to Japanese Patent Application No. 2019-215588 filed on Nov. 28, 2019. Each of the above applications is hereby expressly incorporated by reference, in its entirety, into the present application.

### BACKGROUND OF THE INVENTION

### 1. Field of the Invention

The present invention relates to a polymer-based piezoelectric composite material used for an electroacoustic conversion film or the like used for a speaker, a microphone, or the like, and a method for producing raw-material particles for a composite, the raw-material particles being used for the polymer-based piezoelectric composite material.

### 2. Description of the Related Art

Development of a flexible display using a flexible substrate such as plastics such as an organic EL display is in progress.

In a case where such a flexible display is used as an image display apparatus with a sound generator that reproduces a sound together with an image, such as a television receiver, a speaker that is an audio device for generating a sound is required.

Here, as a speaker shape in the related art, a funnel shape, a so-called cone type, a spherical dome type, and the like are common. However, in a case where such a speaker is to be embedded in the above-mentioned flexible display, there is a concern that the lightness and flexibility, which are the advantages of the flexible display, may be impaired. In addition, in a case where the speaker is attached externally, it is inconvenient to transport the speaker, and it is difficult to install the speaker on a curved wall, which gives rise to a concern that the appearance may be spoiled.

Under such circumstances, for example, JP2008-294493A discloses that a sheet-like flexible piezoelectric film is adopted as a speaker integratable into a flexible display without impairing lightness and flexibility of the speaker.

The piezoelectric film used in JP2008-294493A is a monoaxially stretched film of polyvinylidene fluoride (PVDF) which has been subjected to a high-voltage polarization treatment, and has a property of stretching and contracting in response to an applied voltage.

A flexible display with a rectangular plan view shape, to which a speaker using a piezoelectric film has been integrated, is held in a state where it is loosely bent like a document form such as newspapers and magazines for portable use, and in a case where the screen display is switched vertically and horizontally, it is preferable that the image display surface can be curved not only in the vertical direction but also in the horizontal direction.

However, since the piezoelectric film consisting of monoaxially stretched PVDF has in-plane anisotropy in piezoelectric characteristics thereof, the sound quality greatly differs depending on a bending direction even in a case where the curvature is the same.

On the contrary, examples of a sheet-like piezoelectric material having flexibility, which has no in-plane anisotropy in the piezoelectric characteristics, include a polymer-based piezoelectric composite material in which piezoelectric particles are dispersed in a matrix consisting of a polymer material.

For example, [Toyoki Kitayama, Proceedings of 1971 IEICE General National Conference 366 (1971)] discloses a polymer-based piezoelectric composite material accomplishing both the flexibility of PVDF and the high piezoelectric characteristics of lead zirconate titanate (PZT) ceramics by a polymer-based piezoelectric composite material in which lead zirconate titanate (PZT) particles as a piezoelectric material are mixed with PVDF by solvent casting or hot kneading.

Here, in such a polymer-based piezoelectric composite material, it is preferable to increase a ratio of piezoelectric particles to a matrix in order to improve piezoelectric characteristics, that is, a transfer efficiency. However, the polymer-based piezoelectric composite material has a problem that it is hard and brittle in a case where an amount of the piezoelectric particles with respect to the matrix is large.

As a method for solving this problem, addition of a fluororubber to PVDF in the polymer-based piezoelectric composite material described in [Toyoki Kitayama, Proceedings of 1971 IEICE General National Conference 366 (1971)] to maintain flexibility is disclosed in [Seiichi Shirai, Hiroaki Nomura, Juro Oga, Takeshi Yamada, Nobuki Oguchi, IEICE Technical Report, 24, 15 (1980)].

### SUMMARY OF THE INVENTION

As shown in [Toyoki Kitayama, Proceedings of 1971 IEICE General National Conference 366 (1971)] and [Seiichi Shirai, Hiroaki Nomura, Juro Oga, Takeshi Yamada, Nobuki Oguchi, IEICE Technical Report, 24, 15 (1980)], PZT particles are used as piezoelectric particles of a polymer-based piezoelectric composite material.

PZT is a piezoelectric material which has a composition represented by General Formula Pb(ZrₓTi₁₋ₓ)O₃ and has a good piezoelectric characteristic.

Such PZT particles are usually manufactured by mixing lead oxide powder, zirconium oxide powder, and titanium oxide powder as raw materials, and performing firing.

It is known that in a ferroelectric material having a perovskite structure such as PZT, high piezoelectric characteristics can be obtained by setting a composition of the material to a phase transition boundary morphotoropic phase boundary (MPB) composition. The MPB composition of PZT is a composition in which x in the above-mentioned general formula is near 0.52. That is, the MPB composition of PZT is a composition near Pb(Zr_{0.52}Ti_{0.48})O₃).

In the production of PZT particles (PZT ceramics) by firing, a compositional ratio of Zr and Ti of the obtained particles is substantially the same as the composition of the raw material powder, the so-called charged composition. Accordingly, PZT particles having the MPB composition can be manufactured by charging raw-material particles of a sintered body so that the zirconium oxide powder and the titanium oxide powder have a molar ratio of 0.52:0.48.

By using the sintered MPB composition PZT particles, a polymer-based piezoelectric composite material having good piezoelectric characteristics can be obtained.

However, in recent years, a demand for a piezoelectric characteristic of a polymer-based piezoelectric composite material is increasingly strict, and an emergence of a polymer-based piezoelectric composite material having a higher piezoelectric characteristic is desired.

An object of the present invention is to solve such a problem of the related art, and is thus to provide a polymer-based piezoelectric composite material including PZT particles in a matrix including a polymer material, the polymer-based piezoelectric composite material exhibiting a higher piezoelectric characteristic; and a method for producing raw-material particles for a composite, the raw-material particles being used in the polymer-based piezoelectric composite material.

In order to accomplish the object, the present invention has the following configurations.

[1] A polymer-based piezoelectric composite material comprising lead zirconate titanate particles in a matrix including a polymer material,

in which the lead zirconate titanate particles include a polycrystalline material, and

in a crystal structure of primary particles constituting the polycrystalline material of the lead zirconate titanate particles, a volume fraction occupied by tetragonal particles is 80% or more.

[2] The polymer-based piezoelectric composite material as described in [1],

in which the crystal structure of the primary particles constituting the polycrystalline material of the lead zirconate titanate particles includes the tetragonal particles and rhombohedral particles.

[3] The polymer-based piezoelectric composite material as described in [1] or [2],

in which a tetragonality of the tetragonal particles in the primary particles constituting the polycrystalline material of the lead zirconate titanate particles is 1.023 or more.

[4] The polymer-based piezoelectric composite material as described in any one of [1] to [3],

in which a full width at half maximum of a 200-peak of the tetragonal particles in the primary particles constituting the polycrystalline material of the lead zirconate titanate particles is 0.3 or less.

[5] The polymer-based piezoelectric composite material as described in any one of [1] to [4],

in which the primary particles constituting the polycrystalline material of the lead zirconate titanate particles have an average particle diameter of 1 μm or more.

[6] The polymer-based piezoelectric composite material as described in any one of [1] to [5],

in which the polymer material has a cyanoethyl group.

[7] The polymer-based piezoelectric composite material as described in [6],

in which the polymer material is cyanoethylated polyvinyl alcohol.

[8] A method for producing raw-material particles for a composite, comprising:

a step of manufacturing raw-material particles by mixing lead oxide, zirconium oxide, and titanium oxide, and performing firing;

a step of molding the raw-material particles and performing firing at a temperature of 1,100° C. or higher; and

a step of subjecting a sintered body obtained by performing the firing at 1,100° C. or higher to a pulverization treatment to obtain raw-material particles for a composite.

[9] The method for producing raw-material particles for a composite as described in [8],

in which the raw-material particles for a composite are further subjected to an annealing treatment at 800° C. to 900° C. after performing the pulverization treatment.

According to the present invention, there is provided a polymer-based piezoelectric composite material having excellent piezoelectric characteristics, using PZT particles, and a method for producing raw-material particles for a composite, the raw-material particles being used for the polymer-based piezoelectric composite material.

### BRIEF DESCRIPTION OF THE DRAWINGS

FIG. 1 is a view conceptually showing an example of a polymer-based piezoelectric composite material according to an embodiment of the present invention.

FIG. 2 is a view conceptually showing an example of an XRD pattern of PZT particles.

FIG. 3 is a graph showing an example of a relationship among a firing temperature of PZT particles, an average particle diameter of primary particles, and a volume fraction of tetragonal particles.

FIG. 4 is a graph showing an example of a relationship among a firing temperature of PZT particles, an average particle diameter of primary particles, and a tetragonality of tetragonal particles.

FIG. 5 is a graph showing an example of a relationship among a firing temperature of PZT particles, an average particle diameter of primary particles, and a full width at half maximum of a 200-peak of tetragonal particles.

FIG. 6 is a view conceptually showing an example of a piezoelectric film using the polymer-based piezoelectric composite material of an embodiment of the present invention.

FIG. 7 is a view conceptually showing another example of a piezoelectric film using the polymer-based piezoelectric composite material of the embodiment of the present invention.

FIG. 8 is a conceptual view for describing a method for manufacturing the piezoelectric film shown in FIG. 7.

FIG. 9 is a conceptual view for describing a method for manufacturing the piezoelectric film shown in FIG. 7.

FIG. 10 is a conceptual view for describing a method for manufacturing the piezoelectric film shown in FIG. 7.

FIG. 11 is a view conceptually showing an example of a piezoelectric speaker using the piezoelectric film shown in FIG. 7.

FIG. 12 is a conceptual view for describing a method for measuring a sound pressure of a piezoelectric speaker in Examples.

### DESCRIPTION OF THE PREFERRED EMBODIMENTS

Hereinafter, a polymer-based piezoelectric composite material and a method for producing raw-material particles for a composite of embodiments of the present invention will be described in detail based on suitable Examples shown in the accompanying drawings.

Descriptions of the constituent requirements described below may be made based on representative embodiments of the present invention, but the present invention is not limited to such embodiments.

In the present specification, a numerical range represented by “to” means a range including numerical values before and after “to” as a lower limit value and an upper limit value.

In addition, the figures shown below are conceptual views for describing the present invention, and the thickness of each layer, the size of the piezoelectric particles, the size of the constituent members, and the like are different from the actual values.

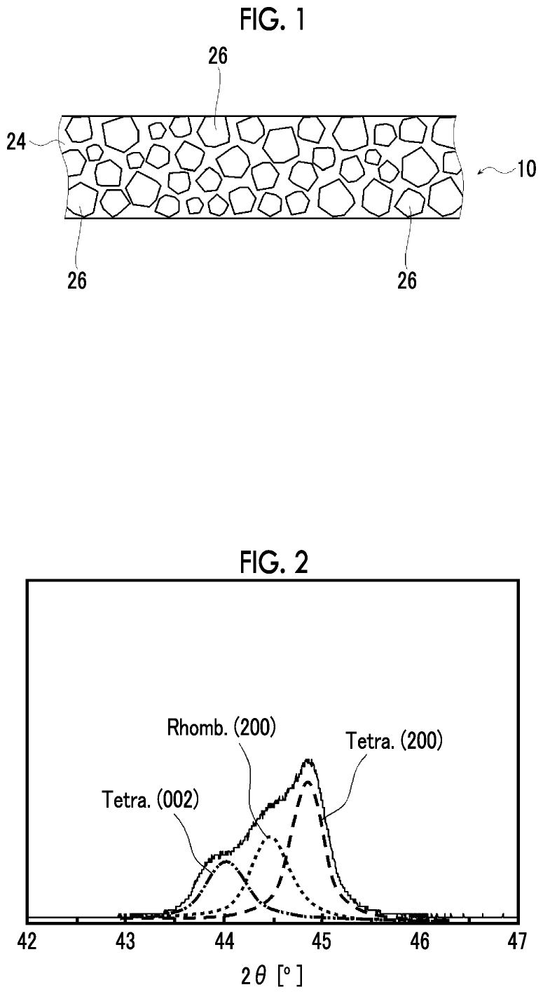

FIG. 1 conceptually shows an example of the polymer-based piezoelectric composite material of the embodiment of the present invention.

As shown in FIG. 1, a polymer-based piezoelectric composite material 10 of the embodiment of the present invention has a configuration in which PZT particles 26 are included as piezoelectric particles in a matrix 24 including a polymer material. In the description below, the “polymer-based piezoelectric composite material 10” is also referred to as a “piezoelectric composite material 10”.

Furthermore, a dispersion state of the PZT particles in the matrix 24 is not limited to a state where the PZT particles are irregularly dispersed as shown in FIG. 1, and the PZT particles may be regularly dispersed.

That is, in the piezoelectric composite material 10 of the embodiment of the present invention, the PZT particles 26 in the matrix 24 may be regularly dispersed or irregularly dispersed in the matrix 24. Incidentally, the dispersion state of the PZT particles 26 in the matrix 24 may be uniform or non-uniform, but is preferably a state where the PZT particles 26 are uniformly dispersed.

In the piezoelectric composite material 10 of the embodiment of the present invention, the PZT particles 26 are particles having PZT (lead zirconate titanate) as a main component.

Moreover, in the present invention, the main component indicates a component included most in a substance, preferably a component included in an amount of 50% by mass or more, and more preferably a component included in an amount of 90% by mass or more.

In the present invention, the PZT particles 26 preferably include only constituent elements of PZT, excluding impurities which are inevitably incorporated.

As is well known, PZT is a solid solution of lead zirconate (PbZrO₃) and lead titanate (PbTIO₃), and is represented by General Formula Pb(ZrₓTi₁₋ₓ)O₃ (hereinafter, General Formula Pb(ZrₓTi₁₋ₓ)O₃ is also referred to as General Formula [I]).

In General Formula [I], x<1 is satisfied. In addition, in General Formula [I], x is an element ratio (molar ratio) of zirconium and titanium, that is, Zr/(Zr+Ti).

In the piezoelectric composite material 10 of the embodiment of the present invention, x in General Formula [I] is not limited.

As described above, it is known that in a ferroelectric material having a perovskite structure such as PZT, high piezoelectric characteristics can be obtained by setting the composition to a phase transition boundary morphotoropic phase boundary (MPB) composition. The MPB composition of PZT is a composition in which x of General Formula [I] is near 0.52 (that is, Pb(Zr_{0.52}Ti_{0.48})O₃).

Accordingly, x in General Formula [I] is preferably close to 0.52. Specifically, x in General Formula [I] is preferably 0.50 to 0.54, more preferably 0.51 to 0.53, and still more preferably 0.52.

In the piezoelectric composite material 10 of the embodiment of the present invention, the PZT particles 26 include a polycrystalline material. In addition, in the PZT particles 26, a volume fraction occupied by tetragonal particles in the crystal structure of the primary particles constituting the polycrystalline material is 80% or more.

Specifically, the crystal structure of the primary particles of the PZT particles 26 has a volume fraction of the tetragonal particles of 100%, or the crystal structure of the primary particles has tetragonal particles and rhombohedral particles and a volume fraction occupied by the tetragonal particles is 80% or more.

As will be shown later in Examples, the piezoelectric composite material 10 of the embodiment of the present invention exhibits high piezoelectric characteristics in a case where the PZT particles 26 have such a configuration. Therefore, a high-quality sound with a high sound pressure can be output by using a piezoelectric film having electrode layers formed on both sides thereof in, for example, a piezoelectric speaker.

The PZT particles are manufactured by mixing lead oxide, zirconium oxide, and titanium oxide, and firing the mixture, followed by pulverizing.

In the polymer-based piezoelectric composite material in which PZT particles are dispersed in a matrix of a polymer material, a voltage applied to the PZT particles is about 5% to 20% of the applied voltage, and is ⅕ or less of that of bulk ceramics to which 100% of a voltage is applied.

Generally, a coercive electric field of a bulk PZT sintered body (PZT ceramics) is about 20 kV/cm. Accordingly, in the piezoelectric composite material in which PZT particles are dispersed in a matrix consisting of a polymer material, an apparent coercive electric field is 100 kV/cm or more, which is five times as high as 20 kV/cm.

This coercive electric field corresponds to 300 V in a case where a thickness of the polymer-based piezoelectric composite material is 30 μm. Therefore, in a case where an AC signal is applied at a general voltage (several V to several tens of V), an electric field strength is much smaller than the coercive electric field, and not to mention a 180° domain switching, for example, a non-180° domain motion such as a 90° domain motion also rarely occurs.

Therefore, unlike bulk ceramics, the piezoelectric performance of a piezoelectric composite material largely depends on stretching and contraction (a reverse piezoelectric effect) of a lattice in the 180° domain. Therefore, higher piezoelectric performance can be obtained by increasing the number of tetragonal particle components having a large dipole moment in the PZT particles.

The piezoelectric composite material 10 of the embodiment of the present invention is a polymer-based piezoelectric composite material formed by dispersing PZT particles 26 dispersed in a matrix 24 including a polymer material, in which a volume fraction occupied by the tetragonal particles in the crystal structure of the primary particles constituting the polycrystalline material of the PZT particles 26 (PZT in the PZT particles 26) is 80% or more. In the description below, “the volume fraction occupied by the tetragonal particles in the crystal structure of the primary particles constituting the polycrystalline material of the PZT particles 26” is also simply referred to as “the volume fraction of the tetragonal particles in the PZT particles 26”.

By having such a configuration, the piezoelectric composite material 10 of the embodiment of the present invention can realize a polymer-based piezoelectric composite material having high piezoelectric performance. For example, by using the piezoelectric composite material as a piezoelectric film which will be described later to manufacture a piezoelectric speaker using this piezoelectric film, a high sound quality piezoelectric speaker having a high sound pressure can be obtained. In addition, a high-sensitivity and high-performance piezoelectric microphone can be obtained by manufacturing a microphone using the piezoelectric film.

In the piezoelectric composite material 10 of the embodiment of the present invention, in a case where the volume fraction of the tetragonal particles in the PZT particles 26 is less than 80%, inconveniences such as not being able to obtain sufficient piezoelectric characteristics and not being able to obtain a large sound pressure as a speaker diaphragm occur.

From the viewpoints of, for example, obtaining high piezoelectric performance and obtaining a large sound pressure as a speaker diaphragm, it is preferable that the volume fraction of the tetragonal particles in the PZT particles 26 is high. The volume fraction of the tetragonal particles in the PZT particles 26 is preferably 80% or more, and more preferably 90% or more.

Furthermore, the volume fraction of the tetragonal particles in the PZT particles 26 may be determined from an XRD pattern obtained by X-ray diffraction (XRD).

That is, as conceptually shown in FIG. 2, a peak intensity I (002)_{T} of a 002-face (Tetra.002) of tetragonal particles near 44°, a peak intensity I (200)_{T} of a 200-face (Tetra.200) of tetragonal particles near 45°, and a peak intensity I (200)_{R} of a 200-face (Rhomb.200) of rhombohedral particles between both the peaks of the tetragonal particles are determined from XRD patterns of 42° to 47°.

From the peak intensity determined above, a volume fraction Rh of the rhombohedral particles is determined by the following equation.

Rh=I(200)_{R}[I(200)_{R}+I(200)_{T}+I(002)_{T}]

Next, a volume fraction Vtet [%] of the tetragonal particles is determined by the following equation.

Vtet [%]=(1−Rh)×100

In the piezoelectric composite material 10 of the embodiment of the present invention, the tetragonality (c/a) of tetragonal particles in the primary particles constituting the polycrystalline material of the PZT particles 26 is not limited. Incidentally, the tetragonality of tetragonal particles is a ratio of the a-axis length which is the minor axis to the c-axis length which is the major axis in the crystal lattice of the tetragonal particles.

The tetragonality of the tetragonal particles of the primary particles of the PZT particles 26 is preferably 1.023 or more, more preferably 1.024 or more, and still more preferably 1.025 or more.

It is preferable that the tetragonality of the tetragonal particles of the primary particles of the PZT particles 26 is set to 1.023 or more from the viewpoint that high piezoelectric performance can be obtained and a large sound pressure can be obtained for a speaker diaphragm.

The tetragonality of the tetragonal particles of the primary particles of the PZT particles 26 may be calculated from a ratio of the c-axis length calculated from the 002-peak position to the a-axis length calculated from the 200-peak position by the XRD measurement.

In addition, the full width at half maximum (FWHM of (200)) of the 200-peak of the tetragonal particles in the primary particles, which is a measure of the crystallinity of the PZT particles 26, is preferably 0.3 or less, and more preferably 0.25 or less. It is preferable that the full width at half maximum of the 200-peak of the tetragonal particles in the primary particles of the PZT particles is 0.3 or less from the viewpoint that high piezoelectric performance can be obtained and a large sound pressure can be obtained for a speaker diaphragm.

In the piezoelectric composite material 10 of the embodiment of the present invention, an average particle diameter of the primary particles constituting the polycrystalline material of the PZT particles 26 is not limited.

The average particle diameter of the primary particles of the PZT particles 26 is preferably 1 μm or more, more preferably 1.5 μm or more, and still more preferably 2.0 μm or more.

It is preferable to set the average particle diameter of the primary particles of the PZT particles 26 to 1 μm or more from the viewpoint that high piezoelectric performance can be obtained and a high sound pressure can be obtained for a speaker diaphragm.

The average particle diameter of the primary particles of the PZT particles 26 may be measured by scattering about 1 g of the PZT particles 26 on a conductive double-sided pressure sensitive adhesive sheet including carbon powder as a conductive filler, and perform an image analysis through observation using a scanning electron microscope (SEM).

Such PZT particles 26, that is, PZT particles used as a raw material for the piezoelectric composite material 10 of the embodiment of the present invention can be manufactured according to the method for producing raw-material particles for a composite of an embodiment of the present invention.

First, lead oxide powder, zirconium oxide powder, and titanium oxide powder are mixed according to a desired composition of the target PZT to prepare a mixed raw material powder. The composition of PZT in the PZT particles 26 substantially matches the composition of the mixed raw material powder, that is, the charged composition.

Next, the mixed raw material powder is fired at about 700° C. to 800° C. for 1 to 5 hours to manufacture raw-material particles.

Furthermore, the raw-material particles may be manufactured by pulverizing the sintered body after firing, as necessary. The pulverizing method is not limited, and a known method such as a method using a ball mill can be used.

Next, the raw-material particles thus manufactured are molded into pellets.

A shape of the pellet is not limited, and various shapes such as a disk shape, a columnar shape, and a bale shape can be used. In addition, molding conditions such as a molding pressure and a molding temperature are not limited, and may be set as appropriate according to the size of a pellet, the molding method, the properties and states of the raw-material particles, and the like.

Next, the pellets of the molded raw-material particles are fired at a temperature of 1,100° C. or higher.

Raw-material particles for a composite serving as the PZT particles 26 of the piezoelectric composite material 10, which have a volume fraction of the tetragonal particles in the PZT particles 26 of 80% or higher and are dense, can be obtained by setting the firing temperature of the pellets to 1,100° C. or higher.

In addition, by setting the firing temperature to 1,100° C. or higher, the average particle diameter of the primary particles of the PZT particles 26 can be set to 1 μm or higher, and further, the tetragonality of the tetragonal particles of the primary particles of the PZT particles 26 can be set to 1.023 or higher.

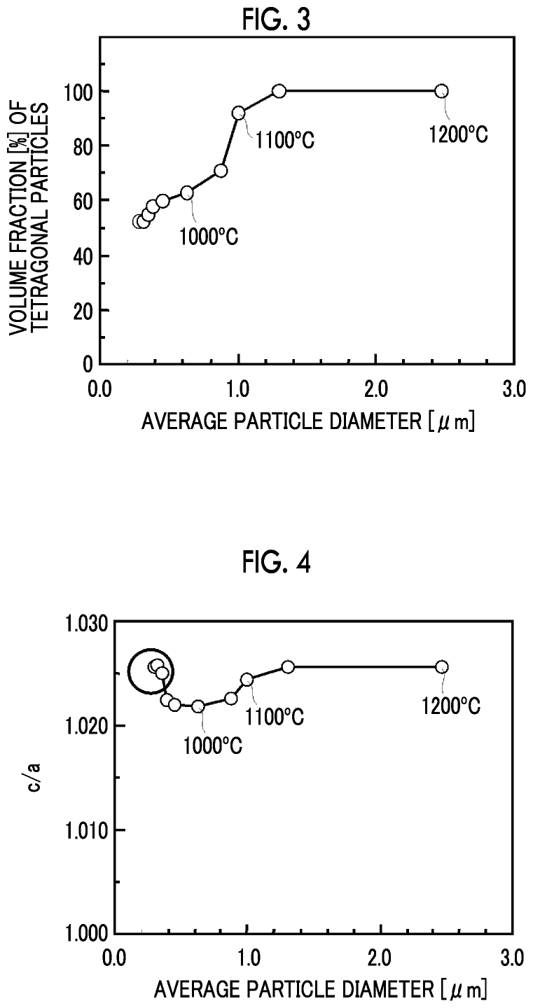

FIG. 3 shows an example of a relationship among the firing temperature of the pellets of the raw-material particles, the average particle diameter of the primary particles of the PZT particles 26, and the volume fraction of the tetragonal particles in the PZT particles 26. In addition, FIG. 4 shows an example of a relationship among the firing temperature of the pellets of the raw-material particles, the average particle diameter of the primary particles of the PZT particles 26, and the tetragonality (c/a) of the tetragonal particles of the primary particles of the PZT particles 26.

FIGS. 3 and 4 are data in a case where firing is performed by changing the firing temperature of the pellets of the raw-material particles from 750° C. to 1,200° C. in an increment of 50° C.

As shown in FIG. 3, by setting the firing temperature of the pellets of the raw-material particles to 1,100° C. or higher, the volume fraction of the tetragonal particles in the PZT particles 26 can be set to 80% or higher, and the average particle diameter of the primary particles of the PZT particles 26 can be set to 1 μm or more.

In addition, as shown in FIG. 4, by setting the firing temperature of the pellets of the raw-material particles to 1,100° C. or higher, the average particle diameter of the primary particles of the PZT particles 26 can be set to 1 μm or higher, and the tetragonality of the tetragonal particles of the primary particles of the PZT particles 26 can be set to 1.023 or higher. Furthermore, in FIG. 4, a region surrounded by ○ and having a small average particle diameter is a region considered to have a low firing temperature and a large amount of the remaining components of the mixed raw material powder. Therefore, there is much lead titanate having a large c-axis length which is a major axis, and apparently, the tetragonality is increased.

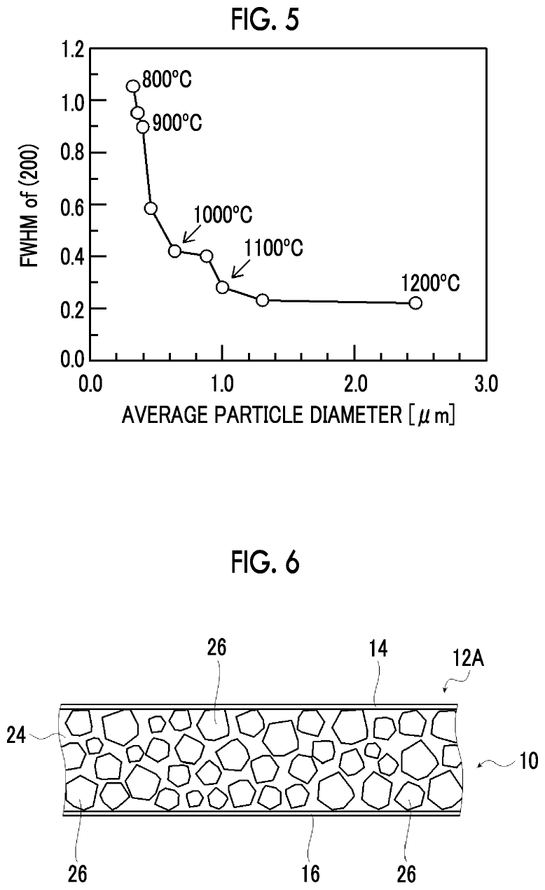

In addition, FIG. 5 shows an example of a relationship among the firing temperature of the pellets of the raw-material particles, the average particle diameter of the primary particles of the PZT particles 26, and the full width at half maximum (FWHM of (200)) of the 200-peak of tetragonal particles of the primary particles of the PZT particles 26.

As shown in FIGS. 3 to 5, in a case where the firing temperature of the pellets of the raw-material particles is lower than 1,100° C., the volume fraction of the tetragonal particles in the PZT particles 26 cannot be set to 80% or more. In addition, in a case where the firing temperature of the pellets of the raw-material particles is lower than 1,100° C., the average particle diameter of the primary particles of the PZT particles 26 cannot be set to 1 μm or more, the tetragonality of the tetragonal particles in the primary particles of the PZT particles 26 cannot be set to 1.023 or more, and further, the full width at half maximum (FWHM of (200)) of the 200-peak of the tetragonal particles in the primary particles of the PZT particles 26 cannot be set to 0.3 or less.

The firing temperature of the pellets of the raw-material particles is preferably 1,100° C. or higher, and more preferably 1,150° C. or higher. The upper limit of the firing temperature is a temperature at which denaturation and decomposition of the raw-material particles do not occur, and is preferably 1,250° C. or lower.

The firing time is not limited and may be set as appropriate according to the size and thickness of the pellets of the raw-material particles, and the like. The firing time is not limited, but is preferably 1 to 5 hours, and more preferably 2 to 4 hours.

The pellets of the raw-material particles are fired, and thus, the obtained sintered body is pulverized to obtain the raw-material particles for a composite, which serve as the PZT particles 26 of the piezoelectric composite material 10. Alternatively, pulverization and sieving are sequentially performed to obtain raw-material particles for a composite which serve as the PZT particles 26 of the piezoelectric composite material 10.

A method for pulverizing the sintered body is not limited, and a known method such as a method using a ball mill can be used.

A mesh size for the sieving is also not limited, and may be selected as appropriate according to a particle diameter of the PZT particles 26 which will be described later, and the like.

In the method for producing raw-material particles for a composite of the embodiment of the present invention, raw-material particles (PZT particles) for a composite are manufactured in this manner, and then preferably, the raw-material particles for a composite are subjected to an annealing treatment (heat treatment) at 800° C. to 900° C.

In a case where the pellet-like sintered body is pulverized, the crystals of the raw-material particles (PZT) for a composite are damaged due to the pulverization, thus causing a strain and the like, and the full width at half maximum (FWHM of (200)) of the 200-peak of the tetragonal particles in the primary particles, which is a measure of the crystallinity of the PZT particles 26, may exceed 0.3.

On the contrary, by subjecting the manufactured raw-material particles for a composite to an annealing treatment at 800° C. to 900° C. after pulverization, the crystallinity of the raw-material particles for a composite is restored, and by setting the full width at half maximum (FWHM of (200)) of the 200-peak of the tetragonal particles to 0.3 or less, a piezoelectric composite material 10 having higher piezoelectric characteristics can be obtained. Furthermore, even in a case where the annealing treatment is performed, the volume fraction and the tetragonality (c/a) of the tetragonal particles of the PZT particles 26 do not change.

A damage to the particles that have been subjected by pulverization can be suitably reduced by setting the temperature of the annealing treatment to 800° C. or higher. In addition, recombination between particles can be suppressed by setting a temperature of the annealing treatment to 900° C. or lower. The temperature of the annealing treatment is more preferably 850° C. to 900° C.

A time for the annealing treatment of the manufactured raw-material particles for a composite is not limited, and may be set as appropriate according to the temperature of the annealing treatment, the amount of the raw-material particles for a composite to be subjected to an annealing treatment, and the like. The time for the annealing treatment of the raw-material particles for a composite is not limited, but is preferably 0.5 to 3 hours, and more preferably 1 to 2 hours.

Incidentally, in a case where the raw-material particles for a composite are subjected to an annealing treatment, sieving may be performed after the annealing treatment. Alternatively, sieving may be performed both after the pulverization of the sintered body of the pellet and after the annealing treatment.

In the piezoelectric composite material 10 of the embodiment of the present invention, the particle diameters of the PZT particles 26 may be selected as appropriate according to the size and use of the piezoelectric composite material 10, and the like.

Here, according to the studies conducted by the present inventors, the particle diameters of the PZT particles 26 are preferably 1 to 30 μm, and more preferably 5 to 10 μm.

Preferred results from the viewpoint of accomplishing both excellent piezoelectric characteristics and flexibility can be obtained by setting the particle diameter of the PZT particles 26 to be in the range.

As shown in FIG. 1, the piezoelectric composite material 10 of the embodiment of the present invention includes PZT particles 26 in a matrix 24 including a polymer material.

Specifically, the piezoelectric composite material 10 of the embodiment of the present invention is formed by dispersing the PZT particles 26 in the matrix 24 including a polymer material as a main component.

Here, the polymer-based piezoelectric composite material obtained by dispersing piezoelectric particles such as PZT particles 26 in a matrix (polymer matrix) including a polymer material preferably satisfies the following requirements. Incidentally, in the present invention, a room temperature is in a range of 0° C. to 50° C.

### (i) Flexibility

For example, in a case of being gripped in a state of being loosely bent like a document form such as a newspaper and a magazine as a portable device, the piezoelectric film is continuously subjected to large bending deformation from the outside at a relatively slow vibration of less than or equal to a few Hz. In this case, in a case where the polymer-based piezoelectric composite material is hard, a large bending stress is generated to that extent, and a crack is generated at the interface between a polymer matrix and piezoelectric particles, which may lead to breakage. Accordingly, the polymer-based piezoelectric composite material is required to have appropriate flexibility. In addition, in a case where strain energy is diffused into the outside as heat, the stress is able to be relieved. Accordingly, the polymer-based piezoelectric composite material is required to have a appropriately large loss tangent.

### (ii) Acoustic Quality

In a speaker, the piezoelectric particles vibrate at a frequency of an audio band of 20 Hz to 20 kHz, and the vibration energy causes the entire diaphragm (polymer-based piezoelectric composite material) to vibrate integrally, whereby a sound is reproduced. Therefore, in order to increase the transmission efficiency of the vibration energy, the polymer-based piezoelectric composite material is required to have appropriate hardness. In addition, in a case where the frequencies of the speaker are smooth as the frequency characteristic thereof, an amount of a change in an acoustic quality in a case where the lowest resonance frequency f₀ is changed in association with a change in the curvature of the speaker decreases. Therefore, the loss tangent of the polymer-based piezoelectric composite material is required to be appropriately large.

It is known that the lowest resonance frequency f₀ of the diaphragm for a speaker is represented by the following equation. Here, s represents a stiffness of the vibration system and m represents a mass.

$$Lowest resonance frequency : {f}_{0} = \frac{1}{2 π} \sqrt{\frac{s}{m}}$$

Here, as a degree of curvature of a piezoelectric film, that is, a radius of curvature of a curved part increases, a mechanical stiffness s decreases, whereby the lowest resonance frequency f₀ decreases. That is, an acoustic quality (volume and frequency characteristics) of the speaker varies depending on the radius of curvature of the piezoelectric film.

That is, the polymer-based piezoelectric composite material is required to exhibit a behavior of being rigid with respect to a vibration of 20 Hz to 20 kHz and being flexible with respect to a vibration of less than or equal to a few Hz. In addition, the loss tangent of a polymer-based piezoelectric composite material is required to be appropriately large with respect to the vibration of all frequencies of 20 kHz or less.

In general, a polymer solid has a viscoelasticity relieving mechanism, and a molecular movement having a large scale is observed as a decrease (relief) in a storage elastic modulus (Young's modulus) or a maximal value (absorption) in a loss elastic modulus along with an increase in temperature or a decrease in frequency. Among these, the relief due to a micro-brownian motion of a molecular chain in an amorphous region is referred to as main dispersion, and an extremely large relieving phenomenon is observed. A temperature at which this main dispersion occurs is a glass transition point (Tg), and the viscoelasticity relieving mechanism is most remarkably observed.

In the polymer-based piezoelectric composite material (piezoelectric composite material 10), the polymer-based piezoelectric composite material exhibiting a behavior of being rigid with respect to a vibration of 20 Hz to 20 kHz and being flexible with respect to a vibration of less than or equal to a few Hz is realized by using a polymer material whose glass transition point is room temperature, that is, a polymer material having a viscoelasticity at room temperature as a matrix. In particular, from the viewpoint that such a behavior is suitably exhibited, it is preferable that the polymer material in which the glass transition point at a frequency of 1 Hz is at room temperature is used for a matrix of the polymer-based piezoelectric composite material.

In the polymer material, it is preferable that the maximal value of a loss tangent Tanδ at a frequency of 1 Hz according to a dynamic viscoelasticity measurement at room temperature is 0.5 or more.

Thus, in a case where the polymer-based piezoelectric composite material is slowly bent due to an external force, stress concentration on the interface between the polymer matrix and the piezoelectric particles at the maximum bending moment portion is relieved, and thus, satisfactory flexibility can be expected.

In addition, in the polymer material, it is preferable that a storage elastic modulus (E′) at a frequency of 1 Hz according to the dynamic viscoelasticity measurement is 100 MPa or more at 0° C. and 10 MPa or less at 50° C.

Thus, a bending moment generated in a case where the polymer-based piezoelectric composite material is slowly bent due to the external force can be reduced, and the polymer-based piezoelectric composite material can exhibit a behavior of being rigid with respect to an acoustic vibration of 20 Hz to 20 kHz.

In addition, it is more suitable that a relative dielectric constant of the polymer material is 10 or more at 25° C. Thus, in a case where a voltage is applied to the polymer-based piezoelectric composite material, a higher electric field is applied to the piezoelectric particles in the polymer matrix, and thus, a large deformation amount can be expected.

However, in contrast, in consideration of ensuring satisfactory moisture resistance and the like, it is suitable that the relative dielectric constant of the polymer material is 10 or less at 25° C.

Suitable examples of the polymer material that satisfies such conditions include cyanoethylated polyvinyl alcohol (cyanoethylated PVA), polyvinyl acetate, polyvinylidene chloride-co-acrylonitrile, a polystyrene-vinyl polyisoprene block copolymer, polyvinyl methyl ketone, and polybutyl methacrylate. In addition, as these polymer materials, a commercially available product such as Hybrar 5127 (manufactured by Kuraray Co., Ltd.) can also be suitably used.

In the piezoelectric composite material 10 of the embodiment of the present invention, these polymer materials are preferably exemplified as the polymer materials constituting the matrix 24.

In the description below, the above-described polymer materials typified by cyanoethylated PVA will also be collectively referred to as the “polymer material having a viscoelasticity at room temperature”.

In the piezoelectric composite material 10 of the embodiment of the present invention, it is more preferable to use a polymer material having a cyanoethyl group, and it is still more preferable to use cyanoethylated PVA as the polymer material constituting the matrix 24.

Furthermore, the polymer material having a viscoelasticity at room temperature may be used alone or in combination (mixture) of two or more kinds thereof.

A plurality of polymer materials may be used in combination, as necessary, in the matrix 24 of the piezoelectric composite material 10 of the embodiment of the present invention.

That is, for the purpose of adjusting dielectric characteristics, mechanical characteristics, and the like, other dielectric polymer materials may be added to the matrix 24 constituting the piezoelectric composite material 10, as necessary, in addition to the polymer material having a viscoelasticity at room temperature.

Examples of the dielectric polymer material which can be added thereto include a fluorine-based polymer such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, or a polyvinylidene fluoride-tetrafluoroethylene copolymer, a polymer containing a cyano group or a cyanoethyl group such as a vinylidene cyanide-vinyl acetate copolymer, cyanoethyl cellulose, cyanoethyl hydroxysaccharose, cyanoethyl hydroxycellulose, cyanoethyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyano ethyl polyacrylamide, cyanoethyl polyacrylate, cyanoethyl pullulan, cyanoethyl polyhydroxymethylene, cyanoethyl glycidol pullulan, cyanoethyl saccharose, or cyanoethyl sorbitol, and synthetic rubber such as nitrile rubber or chloroprene rubber.

Among those, the polymer material having a cyanoethyl group is suitably used.

In addition, in the matrix 24 of the piezoelectric composite material 10, the number of these dielectric polymer materials is not limited to one, and a plurality of kinds of dielectric polymer materials may be added.

In addition, for the purpose of adjusting the glass transition point Tg of the matrix 24, a thermoplastic resin such as a vinyl chloride resin, polyethylene, polystyrene, a methacrylic resin, polybutene, or isobutylene, and a thermosetting resin such as a phenol resin, a urea resin, a melamine resin, an alkyd resin, and mica may be added, in addition to the dielectric polymer materials.

Further, for the purpose of improving the pressure sensitive adhesiveness, a viscosity imparting agent such as rosin ester, rosin, terpene, terpene phenol, and a petroleum resin may be added.

In the matrix 24 of the piezoelectric composite material 10, the addition amount in a case of adding polymer materials other than the polymer material having a viscoelasticity at room temperature is not particularly limited, but is preferably set to 30% by mass or less in terms of the proportion of the polymer materials in the matrix 24.

Thus, the characteristics of the polymer material to be added can be exhibited without impairing the viscoelastic relieving mechanism in the matrix 24, and thus, preferred results, for example, an increase in the dielectric constant, improvement of the heat resistance, and improvement of the adhesiveness between the PZT particles 26 and the electrode layer can be obtained.

The piezoelectric composite material 10 (polymer-based piezoelectric composite material) includes the above-mentioned PZT particles 26 in a matrix including such a polymer material.

A quantitative ratio of the matrix 24 to the PZT particles 26 in the piezoelectric composite material 10 may be set as appropriate according to the size and the thickness of the piezoelectric composite material 10 in the plane direction, the application of the piezoelectric composite material 10, the characteristics required for the piezoelectric composite material 10, and the like.

A volume fraction of the PZT particles 26 in the piezoelectric composite material 10 is preferably in a range of 30% to 80%, and more preferably in a range of 50% to 80%.

Preferred results from the viewpoint of accomplishing both of excellent piezoelectric characteristics and flexibility can be obtained by setting the quantitative ratio of the matrix 24 to the PZT particles 26 to be in the range.

A thickness of the piezoelectric composite material 10 is not limited, and may be set as appropriate according to the size of the piezoelectric composite material 10, the application of the piezoelectric composite material 10, the characteristics required for the piezoelectric composite material 10, and the like.

The thickness of the piezoelectric composite material 10 is preferably 8 to 300 μm, more preferably 8 to 200 μm, still more preferably 10 to 150 μm, and particularly preferably 15 to 100 μm.

Preferred results from the viewpoint of accomplishing both ensuring of the rigidity and appropriately elasticity can be obtained by setting the thickness of the piezoelectric composite material 10 to be in the range.

It is preferable that the piezoelectric composite material 10 is subjected to a polarization treatment (poling) in the thickness direction. The polarization treatment will be described in detail later.

By way of example, such a piezoelectric composite material 10 of the embodiment of the present invention is used as a piezoelectric film 12A having a first electrode layer 14 provided on one surface and a second electrode layer 16 provided on the other surface, as conceptually shown in FIG. 6.

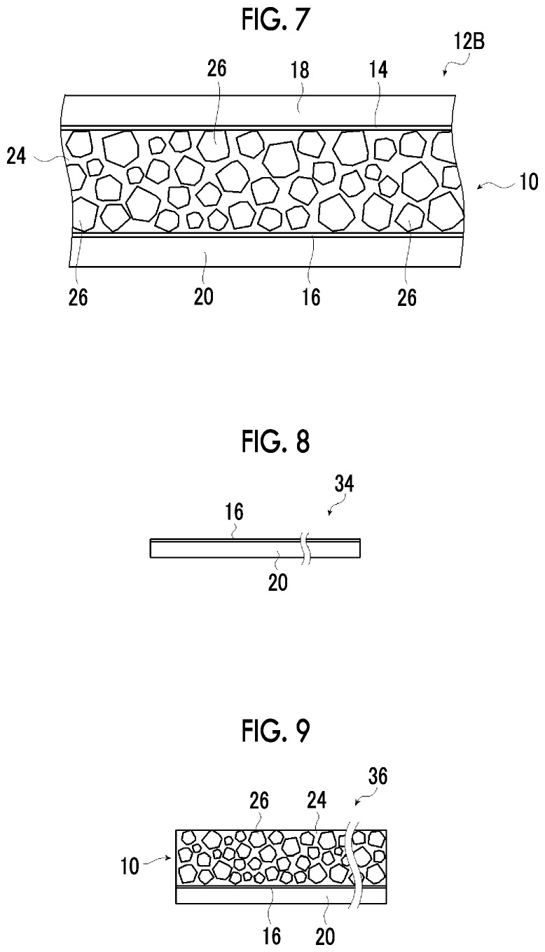

Preferably, the piezoelectric composite material 10 of the embodiment of the present invention is used as a piezoelectric film 12B having a first protective layer 18 on the first electrode layer 14 and further a second protective layer 20 provided on the second electrode layer 16, as conceptually shown in FIG. 7.

In other words, the piezoelectric composite material 10 of the embodiment of the present invention is sandwiched on both surfaces by a pair of electrodes, that is, the first electrode layer 14 and the second electrode layer 16, and preferably further sandwiched between the first protective layer 18 and the second protective layer 20, and is thus used as a piezoelectric film.

In this manner, the region held by the first electrode layer 14 and the second electrode layer 16 is stretched and contracted in the plane direction according to the applied voltage.

Furthermore, in the present invention, the terms of the first and the second in the first electrode layer 14 and the first protective layer 18, and the second electrode layer 16 and the second protective layer 20 are given for convenience to describe the piezoelectric film using the piezoelectric composite material 10 of the embodiment of the present invention.

Accordingly, the terms of the first and the second in the piezoelectric film 12A and the piezoelectric film 12B have no technical meanings and are irrelevant to the actual usage state.

Hereinafter, the piezoelectric film using the piezoelectric composite material 10 of the embodiment of the present invention will be described by taking the piezoelectric film 12B having the first protective layer 18 and the second protective layer 20 as a representative example.

Moreover, the piezoelectric film 12B (piezoelectric film 12A) may have, for example, an affixing layer for affixing the electrode layer and the piezoelectric composite material 10, and the affixing layer for affixing the electrode layer and the protective layer, in addition to the electrode layer and the protective layer.

The affixing agent may be an adhesive or a pressure sensitive adhesive. In addition, for the affixing agent, the same material as the polymer material obtained by removing the PZT particles 26 from the piezoelectric composite material 10, that is, the matrix 24 can also be suitably used. Incidentally, the affixing layer may be provided on both the first electrode layer 14 side and the second electrode layer 16 side, or may be provided only on one of the first electrode layer 14 side and the second electrode layer 16 side.

Further, the piezoelectric film 12B may further have an electrode leading-out part that leads out the electrodes from the first electrode layer 14 and the second electrode layer 16, and an insulating layer which covers a region where the piezoelectric composite material 10 is exposed for preventing a short circuit or the like, in addition to the above-described layers.

The electrode leading-out part may be configured such that a portion where the electrode layer and the protective layer project convexly outside the piezoelectric composite material 10 in the plane direction is provided or configured such that a part of the protective layer is removed to form a hole portion, and a conductive material such as silver paste is inserted into the hole portion so that the conductive material is conducted with the electrode layer.

Furthermore, each electrode layer may have only one or two or more electrode leading-out parts. Particularly in a case of the configuration in which the electrode leading-out part is obtained by removing a part of the protective layer and inserting a conductive material into the hole portion, it is preferable that the electrode layer has three or more electrode leading-out parts in order to more reliably ensure the conduction.

In the piezoelectric film 12B, the first protective layer 18 and the second protective layer 20 have a function of covering the first electrode layer 14 and the second electrode layer 16, and applying appropriate rigidity and mechanical strength to the piezoelectric composite material 10. That is, in the piezoelectric film 12B, the piezoelectric composite material 10 including the matrix 24 and the PZT particles 26 exhibits extremely excellent flexibility under bending deformation at a slow vibration, but may have insufficient rigidity, mechanical strength, and the like, depending on the applications. As a compensation for this, the piezoelectric film 12B is provided with the first protective layer 18 and the second protective layer 20.

The second protective layer 20 and the first protective layer 18 have the same configuration except for the disposition position. Accordingly, in the description below, in a case where it is not necessary to distinguish the second protective layer 20 from the first protective layer 18, both members are collectively referred to as a protective layer.

Furthermore, according to a more preferred aspect, the piezoelectric film 12B in the example illustrated in the figure has the second protective layer 20 and the first protective layer 18 in a manner of being laminated on both electrode layers. However, the present invention is not limited thereto, and a configuration having only one of the second protective layer 20 and the first protective layer 18 may be employed.

The protective layer is not limited, various sheet-like materials can be used as the protective layer, and suitable examples thereof include various resin films. Among these, from the viewpoints of excellent mechanical characteristics and heat resistance, a resin film consisting of polyethylene terephthalate (PET), polypropylene (PP), polystyrene (PS), polycarbonate (PC), polyphenylene sulfide (PPS), polymethylmethacrylate (PMMA), polyetherimide (PEI), polyimide (PI), polyamide (PA), polyethylene naphthalate (PEN), triacetyl cellulose (TAC), and a cyclic olefin-based resin is suitably used.

A thickness of the protective layer is not limited. In addition, the thicknesses of the first protective layer 18 and the second protective layer 20 are basically the same as each other, but may be different from each other.

In a case where the rigidity of the protective layer is extremely high, not only is the stretch and contraction of the piezoelectric composite material 10 constrained, but also the flexibility is impaired. Therefore, it is advantageous that the thickness of the protective layer decreases except for a case where mechanical strength, good handleability for a sheet-like material, and the like are required.

According to the studies conducted by the present inventors, in a case where the thickness of the first protective layer 18 and the thickness of the second protective layer 20 are respectively twice or less the thickness of the piezoelectric composite material 10, preferred results from the viewpoint of accomplishing both ensuring of the rigidity and appropriate elasticity can be obtained.

For example, in a case where the thickness of the piezoelectric composite material 10 is 50 μm and the second protective layer 20 and the first protective layer 18 consist of PET, each of the thickness of the second protective layer 20 and the thickness of the first protective layer 18 is preferably 100 μm or less, more preferably 50 μm or less, and still more preferably 25 μm or less.

In the piezoelectric film 12B, the first electrode layer 14 is formed between the piezoelectric composite material 10 and the first protective layer 18. On the other hand, the second electrode layer 16 is formed between the piezoelectric composite material 10 and the second protective layer 20.

The first electrode layer 14 and the second electrode layer 16 are provided to apply an electric field to the piezoelectric composite material 10 of the piezoelectric film 12B.

Furthermore, the second electrode layer 16 and the first electrode layer 14 are basically the same as each other. Accordingly, in the description below, in a case where it is not necessary to distinguish the second electrode layer 16 from the first electrode layer 14, both members are collectively referred to as an electrode layer.

In the piezoelectric film, a material for forming the electrode layer is not limited and various conductors can be used as the material. Specific examples thereof include conductive polymers such as carbon, palladium, iron, tin, aluminum, nickel, platinum, gold, silver, copper, chromium, molybdenum, alloys thereof, indium tin oxide, and polyethylene dioxythiophene-polystyrene sulfonic acid (PEDOT/PPS).

Among those, copper, aluminum, gold, silver, platinum, and indium tin oxide are suitable. Among these, from the viewpoints of conductivity, cost, and flexibility, copper is more preferable.

In addition, the method of forming the electrode layer is not limited, and various known forming methods such as a vapor-phase deposition method (a vacuum film forming method) such as vacuum vapor deposition or sputtering, film formation using plating, a method of affixing a foil formed of the materials, and a method by application can be used.

Among those, particularly from the viewpoint of ensuring the flexibility of the piezoelectric film 12B, a thin film formed of copper, aluminum, or the like formed by vacuum vapor deposition is suitably used as the electrode layer. Among these, particularly a thin film formed of copper formed by vacuum vapor deposition is suitably used.

A thickness of the first electrode layer 14 and a thickness of the second electrode layer 16 are not limited. In addition, the thicknesses of the first electrode layer 14 and the thicknesses of the second electrode layer 16 may basically be the same as or different from each other.

Here, similarly to the protective layer described above, in a case where the rigidity of the electrode layer is extremely high, not only is the stretch and contraction of the piezoelectric composite material 10 constrained, but also the flexibility is impaired. Therefore, it is advantageous that the thickness of the electrode layer decreases in a case where the electric resistance is not excessively high.

In the piezoelectric film 12B, it is suitable that a product of the thicknesses of the electrode layer and the Young's modulus thereof is less than a product of the thickness of the protective layer and the Young's modulus thereof since the flexibility is not considerably impaired.

For example, in a case of a combination consisting of the protective layer formed of PET (Young's modulus: approximately 6.2 GPa) and the electrode layer formed of copper (Young's modulus: approximately 130 GPa), the thickness of the electrode layer is preferably 1.2 μm or less, more preferably 0.3 μm or less, and still more preferably 0.1 μm or less in a case of assuming that the thickness of the protective layer is 25 μm.

As described above, the piezoelectric film 12B has a configuration in which the piezoelectric composite material 10 including the PZT particles 26 is sandwiched between the first electrode layer 14 and the second electrode layer 16 in the matrix 24 including the polymer material, and is further sandwiched between the first protective layer 18 and the second protective layer 20.

It is preferable that, in such a piezoelectric film 12B, the maximal value at which the loss tangent (tanδ) at a frequency of 1 Hz according to dynamic viscoelasticity measurement is 0.1 or more is present at room temperature.

Thus, even in a case where the piezoelectric film 12B is subjected to bending deformation at a slow vibration of less than or equal to a few Hz from the outside, since the strain energy can be effectively diffused to the outside as heat, occurrence of cracks on the interface between the polymer matrix and the piezoelectric particles can be prevented.

In the piezoelectric film 12B, it is preferable that the storage elastic modulus (E′) at a frequency of 1 Hz according to the dynamic viscoelasticity measurement is 10 to 30 GPa at 0° C. and 1 to 10 GPa at 50° C.

Thus, the piezoelectric film 12B may have large frequency dispersion in the storage elastic modulus (E′) at room temperature. That is, it can exhibit a behavior of being rigid with respect to a vibration of 20 Hz to 20 kHz and being flexible with respect to a vibration of less than or equal to a few Hz.

In addition, in the piezoelectric film 12B, it is preferable that the product of the thickness and the storage elastic modulus (E′) at a frequency of 1 Hz according to the dynamic viscoelasticity measurement is in a range of 1.0×10⁶ to 2.0×10⁶ N/m at 0° C. and in a range of 1.0×10⁵ to 1.0×10⁶ N/m at 50° C.

Thus, the piezoelectric film 12B may have appropriate rigidity and mechanical strength within a range not impairing the flexibility and the acoustic characteristics.

Further, in the piezoelectric film 12B, it is preferable that the loss tangent (Tanδ) at a frequency of 1 kHz at 25° C. is 0.05 or more in a master curve obtained from the dynamic viscoelasticity measurement.

Thus, the frequency of a speaker using the piezoelectric film 12B is smooth as the frequency characteristic thereof, and thus, a change in acoustic quality in a case where the lowest resonance frequency f₀ is changed according to a change in the curvature of the speaker (piezoelectric film 12B) can be decreased.

With regard to the points, the same can also be applied to the piezoelectric film 12A shown in FIG. 6.

Hereinafter, an example of the method for producing the piezoelectric film 12B will be described with reference to the conceptual views in FIGS. 8 to 10.

First, a sheet-like material 34 in which the second electrode layer 16 is formed on a surface of the second protective layer 20, conceptually shown in FIG. 8, is prepared. Further, a sheet-like material 38 in which the first electrode layer 14 is formed on a surface of the first protective layer 18, conceptually shown in FIG. 10, is prepared.

The sheet-like material 34 may be manufactured by forming a copper thin film or the like as the second electrode layer 16 on the surface of the second protective layer 20 using vacuum vapor deposition, sputtering, plating, and the like. Similarly, the sheet-like material 38 may be prepared by forming a copper thin film or the like as the first electrode layer 14 on the surface of the first protective layer 18 using vacuum vapor deposition, sputtering, plating, and the like.

Alternatively, a commercially available sheet-like material in which a copper thin film or the like is formed on a protective layer may be used as the sheet-like material 34 and/or the sheet-like material 38.

The sheet-like material 34 and the sheet-like material 38 may be exactly the same as or different from each other.

Moreover, in a case where the protective layer is extremely thin and thus the handleability is degraded, a protective layer with a separator (temporary support) may be used as necessary. Incidentally, a PET having a thickness of 25 μm to 100 μm or the like can be used as the separator. The separator may be removed after thermal compression bonding of the electrode layer and the protective layer.

Next, as conceptually shown in FIG. 9, a paint (coating composition) serving as the piezoelectric composite material 10 is applied onto the second electrode layer 16 of the sheet-like material 34, and then cured to form the piezoelectric composite material 10. Thus, a laminate 36 in which the sheet-like material 34 and the piezoelectric composite material 10 are laminated is manufactured.

Various methods can be used for forming the piezoelectric composite material 10 depending on a material for forming the piezoelectric composite material 10.

By way of example, first, the coating material is prepared by dissolving the above-mentioned polymer material such as cyanoethylated PVA in an organic solvent, adding the above-mentioned PZT particles 26 thereto, and stirring the solution.

The organic solvent is not limited, and various organic solvents such as dimethylformamide (DMF), methyl ethyl ketone, and cyclohexanone can be used.

In a case where the sheet-like material 34 is prepared and the coating material is prepared, the coating material is cast (applied) onto the sheet-like material 34, and the organic solvent is evaporated and dried. Thus, a laminate 36 having the second electrode layer 16 on the second protective layer 20, and having the piezoelectric composite material 10 laminated on the second electrode layer 16, as shown in FIG. 9, is manufactured.

A casting method for the coating material is not limited, and all known methods (coating devices) such as a bar coater, a slide coater, and a doctor knife can be used.

Alternatively, in a case where the polymer material is a material that can be heated and melted, the laminate 36 as shown in FIG. 9 may be prepared by heating and melting the polymer material to prepare a melt obtained by adding the PZT particles 26 to the melted material, extruding the melt on the sheet-like material 34 shown in FIG. 8 in a sheet shape by carrying out extrusion molding or the like, and cooling the laminate.

Furthermore, as described above, in the piezoelectric film 12B, a polymer piezoelectric material such as PVDF may be added to the matrix 24 in addition to the polymer material having a viscoelasticity at room temperature.

In a case where the polymer piezoelectric material is added to the matrix 24, the polymer piezoelectric material to be added to the coating material may be dissolved. Alternatively, the polymer piezoelectric material to be added may be added to the heated and melted polymer material having a viscoelasticity at room temperature so that the polymer piezoelectric material is heated and melted.

After forming the piezoelectric composite material 10, a calendaring treatment may be performed as necessary. The calendaring treatment may be performed once or a plurality of times.

As is well known, the calendering treatment is a treatment in which a surface to be treated is pressed while being heated by a heating press, a heating roller, and the like to flatten the surface.

Next, the piezoelectric composite material 10 of the laminate 36 in which the second electrode layer 16 is provided on the second protective layer 30 and the piezoelectric composite material 10 is formed on the second electrode layer 16 is subjected to a polarization treatment (poling). The polarization treatment of the piezoelectric composite material 10 may be performed before the calendering treatment, but it is preferable that the polarization treatment is performed after the calendering treatment.

The method of performing a polarization treatment on the piezoelectric composite material 10 is not limited, and a known method can be used. For example, electric field poling in which a DC electric field is directly applied to a target to be subjected to the polarization treatment is exemplified. Furthermore, in a case of performing electric field poling, the electric field poling treatment may be performed using the first electrode layer 14 and the second electrode layer 16 by forming the first electrode layer 14 before the polarization treatment.

In addition, in the piezoelectric composite material 10 of the embodiment of the present invention, it is preferable that the polarization treatment is performed in the thickness direction instead of the plane direction of the piezoelectric composite material 10.

Moreover, the piezoelectric composite material including the PZT particles 26 in the matrix 24 including the polymer material as shown in FIG. 1 can be manufactured by using a sheet-like temporary support having releasability instead of the sheet-like material 34 having the second electrode layer 16 on the second protective layer 30, forming the piezoelectric composite material 10 on the temporary support as described above, and then peeling the temporary support.

Next, as shown in FIG. 10, the sheet-like material 38 which has been prepared in advance is laminated on the piezoelectric composite material 10 side of the laminate 36 which has been subjected to a polarization treatment such that the first electrode layer 14 is directed toward the piezoelectric composite material 10.

Further, the piezoelectric film 12B as shown in FIG. 7 is manufactured by performing thermal compression bonding on the laminate using a heating press device, heating rollers, or the like such that the laminate is sandwiched between the second protective layer 20 and the first protective layer 18 and bonding the laminate 36 and the sheet-like material 38 to each other.

Alternatively, the piezoelectric film 12B may be manufactured by bonding or preferably compression-bonding the laminate 36 and the sheet-like material 38 to each other using an adhesive.

The piezoelectric film 12B to be manufactured in such a manner is polarized in the thickness direction instead of the plane direction, and thus, excellent piezoelectric characteristics are obtained even in a case where a stretching treatment is not performed after the polarization treatment. Therefore, the piezoelectric film 12B has no in-plane anisotropy as a piezoelectric characteristic, and stretches and contracts isotropically in all directions in the plane direction in a case where a driving voltage is applied.

Such a piezoelectric film 12B (piezoelectric film 12A) may be prepared by using a cut sheet-like material 34 and a sheet-like material 38, which have a sheet shape, or the like, or roll-to-roll.

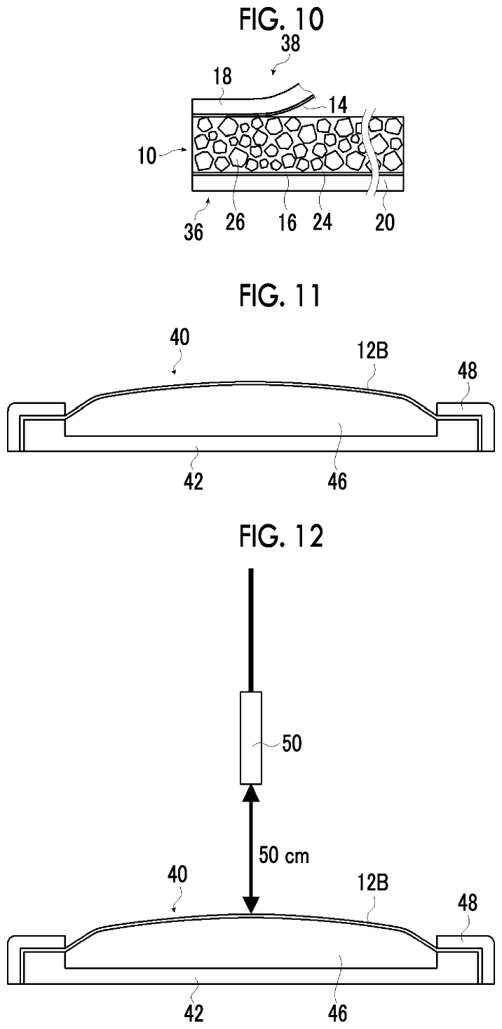

FIG. 11 conceptually shows an example of a flat plate type piezoelectric speaker utilizing the piezoelectric film 12B.

The piezoelectric speaker 40 is a flat plate type piezoelectric speaker that uses the piezoelectric film 12B as a diaphragm that converts an electrical signal into vibration energy. Furthermore, the piezoelectric speaker 40 can also be used as a microphone, a sensor, or the like.

The piezoelectric speaker 40 is configured to have the piezoelectric film 12B, a case 42, a viscoelastic support 46, and a frame 48.

The case 42 is a thin housing formed of plastic or the like and having one surface that is open. Examples of the shape of the housing include a rectangular parallelepiped shape, a cubic shape, and a cylindrical shape.

In addition, the frame 48 is a frame material that has, in the center thereof, a through-hole having the same shape as the open surface of the case 42 and engages with the open surface side of the case 42.

The viscoelastic support 46 is a support used for efficiently converting the stretch and contraction movement of the piezoelectric film 12B into a forward and rearward movement by means of having appropriate viscosity and elasticity, supporting the piezoelectric film 12B, and applying a constant mechanical bias to any place of the piezoelectric film. The back-and-forth movement of the piezoelectric film 12B is, in other words, a movement in a direction perpendicular to a surface of the film. Examples of the viscoelastic support 46 include a wool felt, a nonwoven fabric such as a wool felt including PET and the like, and a glass wool.

The piezoelectric speaker 40 is configured by accommodating the viscoelastic support 46 in the case 42, covering the case 42 and the viscoelastic support 46 with the piezoelectric film 12B, and fixing the frame 48 to the case 42 in a state of pressing the periphery of the piezoelectric film 12B against the upper end surface of the case 42 by the frame 48.

Here, in the piezoelectric speaker 40, the viscoelastic support 46 has a shape in which the height (thickness) is larger than the height of the inner surface of the case 42.

Therefore, in the piezoelectric speaker 40, the viscoelastic support 46 is held in a state of being thinned by being pressed downward by the piezoelectric film 12B at the peripheral portion of the viscoelastic support 46. In addition, similarly, in the peripheral portion of the viscoelastic support 46, the curvature of the piezoelectric film 12B suddenly fluctuates, and a rising portion that decreases in height toward the periphery of the viscoelastic support 46 is formed in the piezoelectric film 12B. Further, the central region of the piezoelectric film 12B is pressed by the viscoelastic support 46 having a square columnar shape and has a (approximately) planar shape.

In the piezoelectric speaker 40, in a case where the piezoelectric film 12B is stretched in the plane direction due to the application of a driving voltage to the first electrode layer 14 and the second electrode layer 16, the rising portion of the piezoelectric film 12B changes the angle in a rising direction due to the action of the viscoelastic support 46 in order to absorb the stretched part. As a result, the piezoelectric film 12B having the planar portion moves upward.

On the contrary, in a case where the piezoelectric film 12B contracts in the plane direction due to the application of the driving voltage to the second electrode layer 16 and the first electrode layer 14, the rising portion of the piezoelectric film 12B changes the angle in a falling direction (a direction approaching the flat surface) in order to absorb the contracted part. As a result, the piezoelectric film 12B having the planar portion moves downward.

The piezoelectric speaker 40 generates a sound by the vibration of the piezoelectric film 12B.

Furthermore, in the piezoelectric film 12B, the conversion from the stretching and contracting movement to vibration can also be achieved by holding the piezoelectric film 12B in a curved state.

Therefore, the piezoelectric film 12B can function as a piezoelectric speaker having flexibility by being simply maintained in a curved state instead of the piezoelectric speaker 40 having rigidity in a flat plate shape, as shown in FIG. 11.

The piezoelectric speaker using the piezoelectric film 12B can be accommodated in a bag or the like by, for example, being rolled or folded using the excellent flexibility. Therefore, with the piezoelectric film 12B, a piezoelectric speaker that can be easily carried even in a case where the piezoelectric speaker has a certain size can be realized.

In addition, as described above, the piezoelectric film 12B has excellent elasticity and excellent flexibility, and has no in-plane anisotropy as a piezoelectric characteristic. Therefore, in the piezoelectric film 12B, a change in acoustic quality regardless of the direction in which the film is bent is small, and a change in acoustic quality with respect to the change in curvature is also small. Accordingly, the piezoelectric speaker using the piezoelectric film 12B has a high degree of freedom of the installation place and can be attached to various products as described above. For example, a so-called wearable speaker can be realized by attaching the piezoelectric film 12B to clothing such as a suit and portable items such as a bag in a curved state.

Further, as described above, the piezoelectric film according to the embodiment of the present invention can be used for a speaker of a display apparatus by affixing the piezoelectric film to a display apparatus having flexibility such as an organic EL display apparatus having flexibility or a liquid crystal display apparatus having flexibility.

As described above, the piezoelectric film 12B stretches and contracts in the plane direction in a case where a voltage is applied, and vibrates suitably in the thickness direction due to the stretch and contraction in the plane direction, and thus, a sound with a high sound pressure can be output and excellent acoustic characteristics are exhibited in a case where the piezoelectric film 12B is used for a piezoelectric speaker or the like.

Such a piezoelectric film 12B, which exhibits excellent acoustic characteristics, that is, high stretch and contraction performance due to piezoelectricity is satisfactorily operated as a piezoelectric vibrating element that vibrates a vibration body such as a diaphragm by laminating a plurality of the piezoelectric films. Since the piezoelectric film 12B has a satisfactory heat dissipation property, heat generation of the film can be prevented even in a case of being laminated and formed into a piezoelectric vibration element, and thus, heating of the diaphragm can be prevented.

Furthermore, in a case of lamination of the piezoelectric films 12B, each piezoelectric film may not have the first protective layer 18 and/or the second protective layer 20 unless there is a possibility of a short circuit. Alternatively, the piezoelectric film that does not have the first protective layer 18 and/or the second protective layer 20 may be laminated through an insulating layer. That is, the piezoelectric film 12A shown in FIG. 6 can also be used as the laminate of the piezoelectric films

By way of example, a speaker in which a laminate of the piezoelectric films 12B is affixed to the diaphragm and the diaphragm is vibrated by the laminate of the piezoelectric films 12B to output a sound may be used. That is, in this case, the laminate of the piezoelectric film 12B acts as a so-called exciter that outputs a sound by vibrating the diaphragm.

By applying a driving voltage to the laminated piezoelectric films 12B, each piezoelectric film 12B stretches and contracts in the plane direction, and the entire laminate of the piezoelectric film 12B stretches and contracts in the plane direction due to the stretch and contraction of each piezoelectric film 12B. The diaphragm to which the laminate has been affixed is bent due to the stretch and contraction of the laminate of the piezoelectric film 12B in the plane direction, and thus, the diaphragm vibrates in the thickness direction. The diaphragm generates a sound using the vibration in the thickness direction. The diaphragm vibrates according to the magnitude of the driving voltage applied to the piezoelectric film 12B and generates a sound according to the driving voltage applied to the piezoelectric film 12B.

Accordingly, the piezoelectric film 12B itself does not output sound in this case.

Even in a case where the rigidity of each piezoelectric film 12B is low and the stretching and contracting force thereof is small, the rigidity is increased by laminating the piezoelectric films 12B, and the stretching and contracting force as the entire laminate is increased. As a result, in the laminate of the piezoelectric films 12B, even in a case where the diaphragm has a certain degree of rigidity, the diaphragm is sufficiently bent with a large force and the diaphragm can be sufficiently vibrated in the thickness direction, whereby the diaphragm can generate a sound.

In the laminate of the piezoelectric film 12B, the number of laminated piezoelectric films 12B is not limited, and the number of sheets set such that a sufficient amount of vibration is obtained may be set as appropriate according to, for example, the rigidity of the diaphragm to be vibrated.

Furthermore, it is also possible to use one piezoelectric film 12B as a similar exciter (piezoelectric vibrating element) in a case where the piezoelectric film has a sufficient stretching and contracting force.

The diaphragm vibrated by the laminate of the piezoelectric film 12B is not limited, and various sheet-like materials (such as plate-like materials and films) can be used.

Examples thereof include a resin film consisting of polyethylene terephthalate (PET) and the like, foamed plastic consisting of foamed polystyrene and the like, a paper material such as a corrugated cardboard material, a glass plate, and wood. Further, a device such as a display apparatus may be used as the diaphragm in a case where the device can be sufficiently bent.

It is preferable that the laminate of the piezoelectric film 12B is obtained by affixing adjacent piezoelectric films with an affixing layer (affixing agent). In addition, it is preferable that the laminate of the piezoelectric film 12B and the diaphragm are also affixed to each other with an affixing layer.

The affixing layer is not limited, and various layers that can affix materials to be affixed can be used. Accordingly, the affixing layer may consist of a pressure sensitive adhesive or an adhesive. It is preferable that an adhesive layer consisting of an adhesive is used from the viewpoint that a solid and hard affixing layer is obtained after the affixing.

With regard to the above point, the same can also be applied to the laminate formed by folding the long piezoelectric film 12B which will be described later.

In the laminate of the piezoelectric films 12B, the polarization direction of each piezoelectric film 12B to be laminated is not limited. Furthermore, as described above, the polarization direction of the piezoelectric film 12B is the polarization direction in the thickness direction.

Accordingly, in the laminate of the piezoelectric films 12B, the polarization directions may be the same for all the piezoelectric films 12B, and piezoelectric films having different polarization directions may be present.

Here, in the laminate of the piezoelectric films 12B, it is preferable that the piezoelectric films 12B are laminated such that the polarization directions of the adjacent piezoelectric films 12B are opposite to each other.

In the piezoelectric film 12B, the polarity of the voltage to be applied to the piezoelectric composite material 10 depends on the polarization direction of the piezoelectric composite material 10. Accordingly, even in a case where the polarization direction is directed from the first electrode layer 14 toward the second electrode layer 16 or from the second electrode layer 16 toward the first electrode layer 14, the polarity of the first electrode layer 14 and the polarity of the second electrode layer 16 in all the piezoelectric films 12B to be laminated are set to be the same polarity.

Accordingly, by reversing the polarization directions of the adjacent piezoelectric films 12B, even in a case where the electrode layers of the adjacent piezoelectric films 12B come into contact with each other, the electrode layers in contact with each other have the same polarity, and thus, there is no risk of a short circuit.

The laminate of the piezoelectric film 12B may be configured such that a long piezoelectric film 12B is folded back, for example, once or more times, or preferably a plurality of times to laminate a plurality of layers of the piezoelectric films 12B.

The configuration in which the long piezoelectric film 12B is folded back and laminated has the following advantages.

That is, in the laminate in which a plurality of cut sheet-like piezoelectric films 12B are laminated, the first electrode layer 14 and the second electrode layer 16 need to be connected to a driving power source for each piezoelectric film. On the contrary, in the configuration in which the long piezoelectric film 12B is folded back and laminated, only one sheet of the long piezoelectric film 12B can form the laminate. In addition, in the configuration in which the long piezoelectric film 12B is folded back and laminated, only one power source is required for applying the driving voltage, and the electrode may be pulled out from the piezoelectric film 12B at one place.

Further, in the configuration in which the long piezoelectric film 12B is folded back and laminated, the polarization directions of the adjacent piezoelectric films 12B are inevitably opposite to each other.

Hereinbefore, the polymer-based piezoelectric composite material and the method for producing raw-material particles for a composite of the embodiments of the present invention have been described in detail, but the present invention is not limited to the above-described examples, and various improvements or modifications may be made within a range not departing from the scope of the present invention.

### EXAMPLES

Hereinafter, the polymer-based piezoelectric composite material and the method for producing raw-material particles for a composite of the embodiments of the present invention will be described in more detail with reference to specific Examples of the present invention.

### Example 1

Lead oxide powder, zirconium oxide powder, and titanium oxide powder were wet-mixed in a ball mill for 12 hours to prepare mixed raw material powder. In this case, the amounts of the respective oxides were Zr=0.52 mol and Ti=0.48 mol with respect to Pb=1 mol.

This mixed raw material powder was put into a crucible and fired at 800° C. for 5 hours to manufacture raw-material particles.

The manufactured raw-material particles were pulverized by a ball mill for 12 hours.

The pulverized raw-material particles were molded into disc-like pellets. Polyvinyl alcohol was used as a binder and the molding pressure was set to 100 MPa.

The pellets of the molded raw-material particles were fired at 1,100° C. for 3 hours to obtain a sintered body. The firing was performed in air.

The obtained sintered body was pulverized by a ball mill for 12 hours to obtain PZT particles (raw-material particles for a composite) which are raw materials for a polymer-based piezoelectric composite material.

Further, the manufactured PZT particles were subjected to an annealing treatment at 900° C. for 1 hour.

The annealing-treated PZT particles were sieved with a mesh of 30 μm to obtain annealing-treated PZT particles.

The crystal structure of the PZT particles was investigated by a powder XRD method using an X-ray diffraction meter (Rint Ultima III manufactured by Rigaku Corporation). A peak intensity I (002)_{T} of a 002-face of tetragonal particles near 44°, a peak intensity I (200)_{T} of a 200-face of tetragonal particles near 45°, and a peak intensity I (200)_{R} of a 200-face of rhombohedral particles between both peaks were determined from the obtained XRD pattern. From the obtained peak intensity, a volume fraction of the tetragonal particles in the crystal structure of the PZT particles was calculated as described above.

As a result, a volume fraction (Vtet) of the tetragonal particles in the crystal structure of the manufactured PZT particles was 91%.

For the manufactured PZT particles, a tetragonality (c/a) of the tetragonal particles was calculated from the c-axis length calculated from a 002-peak position by the XRD measurement and the a-axis length calculated from a 200-peak position. As a result, the tetragonality of the PZT particles was 1.023.

Further, 1 g of the manufactured PZT particles was sampled and scattered on a conductive double-sided pressure sensitive adhesive sheet including carbon powder as a conductive filler. The scattered PZT particles were observed with SEM (HD-2300 manufactured by Hitachi High-Technologies Corporation) to perform image analysis, and an average particle diameter of the primary particles was measured. As a result, the average particle diameter of the primary particles of the PZT particles was 1.0 μm.

The piezoelectric film shown in FIG. 7 was manufactured by the method shown in FIGS. 8 to 10, using the manufactured PZT particles.

First, cyanoethylated PVA (CR-V, manufactured by Shin-Etsu Chemical Co., Ltd.) was dissolved in dimethylformamide (DMF) at the following compositional ratio. Thereafter, the manufactured PZT particles were added to the solution at the following compositional ratio, and the solution was stirred using a propeller mixer (rotation speed of 2000 rpm), thereby preparing a coating material that forms a polymer-based piezoelectric composite material.

| | |
|---|---|
| •PZT Particles | 300 parts by mass |
| •Cyanoethylated PVA | 30 parts by mass |
| •DMF | 70 parts by mass |

On one hand, a sheet-like material obtained by performing vacuum vapor deposition on a copper thin film having a thickness of 0.1 μm was prepared on a PET film having a thickness of 4 μm. That is, in the present example, the first electrode layer and the second electrode layer are copper-deposited thin films having a thickness of 0.1 m, and the first protective layer and the second protective layer are PET films having a thickness of 4 μm.

The coating material for forming a polymer-based piezoelectric composite material prepared in advance was applied onto the second electrode layer (copper vapor deposition thin film) of a sheet-like material, using a slide coater. Furthermore, the second electrode layer was coated with th coating material such that the film thickness of the coating film after being dried reached 40 μm.

Next, the material obtained by coating the sheet-like material with the coating material was heated and dried on a hot plate at 120° C. to evaporate DMF. Thus, a laminate having a second electrode layer made of copper on the second protective layer made of PET and the polymer-based piezoelectric composite material having a thickness of 40 μm was provided thereon was manufactured.

The manufactured polymer-based piezoelectric composite material was subjected to a polarization treatment in the thickness direction.

The sheet-like material was laminated on the laminate which had been subjected to the polarization treatment in a state where the first electrode layer (copper thin film side) was directed toward the piezoelectric composite material.

Next, the piezoelectric film as shown in FIG. 7 was manufactured by performing thermal compression bonding on the laminate of the laminate and the sheet-like material at a temperature of 120° C. using a laminator device, and affixing and adhering the piezoelectric composite material and the first electrode layer to each other.

### Example 2

PZT particles were manufactured in the same manner as in Example 1, except that the annealing treatment was not performed.

Using these PZT particles, a piezoelectric film was manufactured in the same manner as in Example 1.

### Example 3

PZT particles were manufactured in the same manner as in Example 1, except that the firing temperature of the pellets of the raw-material particles was set to 1,200° C.

Using these PZT particles, a piezoelectric film was manufactured in the same manner as in Example 1.

### Example 4

PZT particles were manufactured in the same manner as in Example 3, except that the annealing treatment was not performed.

Using these PZT particles, a piezoelectric film was manufactured in the same manner as in Example 1.

### Comparative Example 1

PZT particles were manufactured in the same manner as in Example 1, except that the firing temperature of the pellets of the raw-material particles was set to 1,000° C.

Using these PZT particles, a piezoelectric film was manufactured in the same manner as in Example 1.

### Comparative Example 2

PZT particles were manufactured in the same manner as in Comparative Example 1, except that the annealing treatment was not performed.

Using these PZT particles, a piezoelectric film was manufactured in the same manner as in Example 1.

For the PZT particles manufactured in Examples 2 to 4 and Comparative Examples 1 and 2, a volume fraction (Vtet) occupied by the tetragonal particles in the PZT particles, a tetragonality (c/a) of the primary particles (as in Example 1), and an average particle diameter of the primary particles were measured.

### Manufacture of Piezoelectric Speaker and Measurement of Sound Pressure

The piezoelectric speakers shown in FIG. 11 were manufactured, using the manufactured piezoelectric films.

First, a rectangular test piece having a size of 210×300 mm (A4 size) was cut out from the manufactured piezoelectric film. The cut-out piezoelectric film was placed on a 210×300 mm case in which glass wool serving as a viscoelastic support was stored in advance as shown in FIG. 11, and the peripheral portion was pressed by a frame to impart an appropriate tension and an appropriate curvature to the piezoelectric film, thereby manufacturing a piezoelectric speaker as shown in FIG. 11.

Furthermore, the depth of the case was set to 9 mm, the density of glass wool was set to 32 kg/m³, and the thickness before assembly was set to 25 mm.

A 1 kHz sine wave was input to the manufactured piezoelectric speaker as an input signal through a power amplifier, and the sound pressure was measured with a microphone 50 placed at a distance of 50 cm from the center of the speaker as shown in FIG. 12.

The results are listed in the table below.

TABLE 1

| | Comparative | | Comparative | | | | | | | | | |
|---|---|---|---|---|---|---|---|---|---|---|---|---|
| | Example 1 | | Example 2 | | Example 1 | | Example 2 | | Example 3 | | Example 4 | |
| Firing | 1,000° | C. | 1,000° | C. | 1,100° | C. | 1,100° | C. | 1,200° | C. | 1,200° | C. |
| temperature | | | | | | | | | | | | |
| Annealing | Performed | | Not | | Performed | | Not | | Performed | | Not | |
| | | | performed | | | | performed | | | | performed | |
| Vtet | 62% | | 62% | | 91% | | 91% | | 100% | | 100% | |
| c/a | 1.002 | | 1.002 | | 1.023 | | 1.023 | | 1.025 | | 1.025 | |
| Average particle | 0.7 | μm | 0.7 | μm | 1.0 | μm | 1.0 | μm | 2.5 | μm | 2.5 | μm |
| diameter | | | | | | | | | | | | |
| Sound pressure | 67 | dB | 66 | dB | 84 | dB | 81 | dB | 85 | dB | 83 | dB |

As shown in the table above, the piezoelectric speaker with a piezoelectric film using the polymer-based piezoelectric composite material of the embodiment of the present invention, in which a volume fraction (Vtet) of the tetragonal particles in the PZT particles is 80% or more, makes it possible to obtain a higher sound pressure, as compared with a piezoelectric speaker with a piezoelectric film using a polymer-based piezoelectric composite material in the related art, in which a volume fraction (Vtet) of the tetragonal particles in the PZT particles is less than 80%. That is, the polymer-based piezoelectric composite material of the embodiment of the present invention has high piezoelectric characteristics.

In addition, in the manufacture of the PZT particles (raw-material particles for a composite), a higher sound pressure can be obtained by subjecting the PZT particles which have been fired and pulverized to an annealing treatment. That is, the piezoelectric characteristics of the polymer-based piezoelectric composite material of the embodiment of the present invention can be further improved by annealing the PZT particles that have been fired and pulverized.

From the results above, the effect of the present invention is apparent.

### EXPLANATION OF REFERENCES

10: (polymer-based) piezoelectric composite material

12A, 12B: piezoelectric film

14: first electrode layer

16: second electrode layer

18: first protective layer

20: second protective layer

24: matrix

26: PZT particles

34, 38: sheet-like material

36: laminate

40: piezoelectric speaker

42: case

46: viscoelastic support

48: frame

50: microphone

What is claimed is:

1. A polymer-based piezoelectric composite material comprising:
lead zirconate titanate particles in a matrix including a polymer material,
wherein the lead zirconate titanate particles include a polycrystalline material, and
in a crystal structure of primary particles constituting the polycrystalline material of the lead zirconate titanate particles, a volume fraction occupied by tetragonal particles is 80% or more.

2. The polymer-based piezoelectric composite material according to claim 1,
wherein the crystal structure of the primary particles constituting the polycrystalline material of the lead zirconate titanate particles includes the tetragonal particles and rhombohedral particles.

3. The polymer-based piezoelectric composite material according to claim 1,
wherein a tetragonality of the tetragonal particles in the primary particles constituting the polycrystalline material of the lead zirconate titanate particles is 1.023 or more.

4. The polymer-based piezoelectric composite material according to claim 1,
wherein a full width at half maximum of a 200-peak of the tetragonal particles in the primary particles constituting the polycrystalline material of the lead zirconate titanate particles is 0.3 or less.

5. The polymer-based piezoelectric composite material according to claim 1,
wherein the primary particles constituting the polycrystalline material of the lead zirconate titanate particles have an average particle diameter of 1 μm or more.

6. The polymer-based piezoelectric composite material according to claim 1,
wherein the polymer material has a cyanoethyl group.

7. The polymer-based piezoelectric composite material according to claim 6,
wherein the polymer material is cyanoethylated polyvinyl alcohol.

8. A method for producing raw-material particles for a composite, comprising:
a step of manufacturing raw-material particles by mixing lead oxide, zirconium oxide, and titanium oxide, and performing firing;
a step of molding the raw-material particles and performing firing at a temperature of 1,100° C. or higher; and
a step of subjecting a sintered body obtained by performing the firing at 1,100° C. or higher to a pulverization treatment to obtain raw-material particles for a composite.

9. The method for producing raw-material particles for a composite according to claim 8,
wherein the raw-material particles for a composite are further subjected to an annealing treatment at 800° C. to 900° C. after performing the pulverization treatment.

10. The polymer-based piezoelectric composite material according to claim 2,
wherein a tetragonality of the tetragonal particles in the primary particles constituting the polycrystalline material of the lead zirconate titanate particles is 1.023 or more.

11. The polymer-based piezoelectric composite material according to claim 2,
wherein a full width at half maximum of a 200-peak of the tetragonal particles in the primary particles constituting the polycrystalline material of the lead zirconate titanate particles is 0.3 or less.

12. The polymer-based piezoelectric composite material according to claim 2,
wherein the primary particles constituting the polycrystalline material of the lead zirconate titanate particles have an average particle diameter of 1 μm or more.

13. The polymer-based piezoelectric composite material according to claim 2,
wherein the polymer material has a cyanoethyl group.

14. The polymer-based piezoelectric composite material according to claim 3,
wherein a full width at half maximum of a 200-peak of the tetragonal particles in the primary particles constituting the polycrystalline material of the lead zirconate titanate particles is 0.3 or less.

15. The polymer-based piezoelectric composite material according to claim 3,
wherein the primary particles constituting the polycrystalline material of the lead zirconate titanate particles have an average particle diameter of 1 μm or more.

16. The polymer-based piezoelectric composite material according to claim 3,
wherein the polymer material has a cyanoethyl group.

17. The polymer-based piezoelectric composite material according to claim 4,
wherein the primary particles constituting the polycrystalline material of the lead zirconate titanate particles have an average particle diameter of 1 μm or more.

18. The polymer-based piezoelectric composite material according to claim 4,
wherein the polymer material has a cyanoethyl group.

19. The polymer-based piezoelectric composite material according to claim 5,
wherein the polymer material has a cyanoethyl group.
